(19) United States
(12) Patent Application Publication
(10) Pub. No.: US 2026/0337759 A1
(43) Pub. Date: Oct. 29, 2026

(54) SPUTTERING APPARATUS AND ELECTRONIC DEVICE MANUFACTURED BY THE SAME

(71) Applicant: Samsung Display Co., LTD., Yongin-si (KR)

(72) Inventors: JEONGIL LEE, Yongin-si (KR); MYUNGSOO HUH, Yongin-si (KR); DOOSEON YU, Yongin-si (KR)

(21) Appl. No.: 19/634,241

(22) Filed: Mar. 31, 2026

(30) Foreign Application Priority Data
Apr. 25, 2025 (KR) 10-2025-0054854

(51) Int. Cl. C23C 14/35

(52) U.S. Cl. CPC C23C 14/35

(57) ABSTRACT

A sputtering apparatus includes a magnet bar including a plurality of magnet modules, and a target module spaced apart from the magnet bar, and disposed above the magnet bar. Each of the plurality of magnet modules includes a yoke, a first permanent magnet, a second permanent magnet, a first electromagnet, and a second electromagnet, the first permanent magnet and the second permanent magnet are disposed on a top surface of the yoke to be spaced apart from each other, and each of the first electromagnet and the second electromagnet is disposed between the first permanent magnet and the second permanent magnet, and is provided in a form of being wounded on a portion of the yoke.

This application claims priority to Korean Patent Application No. 10-2025-0054854, filed on Apr. 25, 2025, and all the benefits accruing therefrom under 35 U.S.C. § 119, the content of which in its entirety is herein incorporated by reference.

### BACKGROUND

### 1. Field

Embodiments of the disclosure described herein relate to a sputtering apparatus and an electronic device manufactured by the same, and more particularly, relate to a sputtering apparatus that may improve process reliability, and an electronic device manufactured by the same.

### 2. Description of the Related Art

A sputtering apparatus is a device that deposits a thin film on a substrate during the manufacturing of semiconductors, flat panel displays (“FPDs”), such as liquid crystal displays (“LCDs”) and organic light-emitting displays (“OLEDs”), or solar cells. Furthermore, a sputtering apparatus may be used in a roll-to-roll device. As an example, a magnetron sputtering apparatus injects gas into a vacuumed chamber to generate plasma, collides ionized gas particles with a target material that is to be deposited, and deposits particles sputtered through collision with a substrate. In this case, to form magnetic field lines in the target, a magnet module is disposed on a rear surface of the target opposite to the substrate. That is, the substrate is provided on a front side of the target, and the magnet module is provided on a rear side of the target. The magnet module generally uses a permanent magnet. The magnetron sputtering apparatus is widely used because it may manufacture a thin film at a relatively low temperature, ions accelerated by an electric field are densely deposited on the substrate, and the deposition speed is high.

### SUMMARY

In an embodiment, embodiments of the disclosure provide a sputtering apparatus that may improve process reliability, and an electronic device manufactured by the same.

In an embodiment of the disclosure, a sputtering apparatus may include a magnet bar including a plurality of magnet modules, and a target module spaced apart from the magnet bar, and disposed above the magnet bar, each of the plurality of magnet modules may include a yoke, a first permanent magnet, a second permanent magnet, a first electromagnet, and a second electromagnet, the first permanent magnet and the second permanent magnet may be disposed on a top surface of the yoke to be spaced apart from each other, and each of the first electromagnet and the second electromagnet may be disposed between the first permanent magnet and the second permanent magnet, and is provided in a form of being wounded on a portion of the yoke.

In an embodiment, the first permanent magnet may include a first part and a second part extending in a first direction, and the second permanent magnet may be disposed between the first part and the second part in a second direction crossing the first direction.

In an embodiment, the first electromagnet may be disposed between the first part and the second permanent magnet in the second direction, and the second electromagnet may be disposed between the second part and the second permanent magnet in the second direction.

In an embodiment, the first electromagnet may be wound around the yoke in a coil form between the first part and the second permanent magnet, the second electromagnet may be wound around the yoke in a coil form between the second part and the second permanent magnet, and a direction, in which the first electromagnet may be wound around the yoke, is opposite to a direction, in which the second electromagnet is wound around the yoke.

In an embodiment, the yoke may include a first through-hole provided between the first part and the second permanent magnet, and through which the first electromagnet passes, and a second through-hole provided between the second part and the second permanent magnet, and through which the second electromagnet passes.

In an embodiment, each of the plurality of magnet modules may include an internal area of the first electromagnet and the second electromagnet in a cross-section, and an external area of the first electromagnet and the second electromagnet in the cross-section.

In an embodiment, the plurality of magnet modules may include a first magnet module, a second magnet module, and a third magnet module arranged in a first direction, and the first magnet module may be disposed between the second magnet module and the third magnet module, in the first direction.

In an embodiment, a direction, in which the first electromagnet of the first magnet module is wound around the yoke, may be opposite to a direction, in which the first electromagnet of the second magnet module and the first electromagnet of the third magnet module are wound around the yoke, and a direction, in which the second electromagnet of the first magnet module is wound around the yoke, may be opposite to a direction, in which the second electromagnet of the second magnet module and the second electromagnet of the third magnet module are wound around the yoke.

In an embodiment, a distance between at least one of the plurality of magnet modules and the target module may be different from distances between remaining magnet modules of the plurality of magnet modules and the target module.

In an embodiment, the plurality of magnet modules may be connected to each other in parallel, and the first electromagnet and the second electromagnet may be connected to each other in series.

In an embodiment, the first electromagnet and the second electromagnet may be connected to a direct-current-to-direct-current (“DC”) power source.

In an embodiment, the magnet bar may further include a plurality of resistors connected to the plurality of magnet modules, respectively, and each of the plurality of resistors may be a variable resistor.

In an embodiment, the magnet bar may further include a plurality of switching circuits connected to the plurality of magnet modules, respectively, and each of the plurality of switching circuits may include a plurality of switching elements and a plurality of sub-resistors connected to the plurality of switching elements, respectively, and having different resistance values from each other.

In an embodiment, the magnet bar may further include a plurality of DC power sources connected to the plurality of magnet modules, respectively.

In an embodiment, the magnet bar may further include a cooling element disposed on a bottom surface of the yoke.

In an embodiment, the magnet bar may further include a cooling water line disposed on a bottom surface of the yoke or disposed in an interior of the yoke.

In an embodiment of the disclosure, a sputtering apparatus includes a magnet bar including a plurality of magnet modules and a plurality of resistors connected to the plurality of magnet modules, respectively, and a target module spaced apart from the magnet bar, and disposed above the magnet bar, each of the plurality of magnet modules may include a yoke, a first electromagnet, and a second electromagnet, and the first electromagnet and the second electromagnet may be provided in a form of being wound around a portion of the yoke.

In an embodiment, each of the plurality of magnet modules may further include a first permanent magnet and a second permanent magnet, the first permanent magnet and the second permanent magnet may be disposed on a top surface of the yoke to be spaced apart from each other, and each of the first electromagnet and the second electromagnet may be disposed between the first permanent magnet and the second permanent magnet.

In an embodiment, the first permanent magnet may include a first part and a second part extending in a first direction, and the second permanent magnet may be disposed between the first part and the second part in a second direction crossing the first direction.

In an embodiment of the disclosure, an electronic device may include a display device manufactured by a sputtering apparatus, and a processor that drives the display device, the sputtering apparatus may include a magnet bar including a plurality of magnet modules, and a target module spaced apart from the magnet bar, and disposed above the magnet bar, each of the plurality of magnet modules may include a yoke, a first permanent magnet, a second permanent magnet, a first electromagnet, and a second electromagnet, the first permanent magnet and the second permanent magnet may be disposed on a top surface of the yoke to be spaced apart from each other, and each of the first electromagnet and the second electromagnet may be disposed between the first permanent magnet and the second permanent magnet, and is provided in a form of being wounded on a portion of the yoke.

### BRIEF DESCRIPTION OF THE DRAWINGS

The above and other embodiments, advantages and features of the disclosure will become apparent by describing in detail embodiments thereof with reference to the accompanying drawings.

FIG. 1 is a plan view of an embodiment of a magnet bar of the disclosure.

FIG. 2 is a cross-sectional view of the magnet bar taken along cutting line I-I′ of FIG. 1.

FIG. 3 is a cross-sectional view of the magnet bar taken along cutting line II-II′ of FIG. 1.

FIG. 4 is a cross-sectional view of the magnet bar viewed from a rear side according to FIG. 1.

FIG. 5 is a cross-sectional view of an embodiment of the magnet bar taken along cutting line II-II′ of FIG. 1 of the disclosure.

FIG. 6 is a perspective view illustrating a direction of a magnetic field generated by a first permanent magnet and a second permanent magnet according to a comparative example.

FIG. 7 is a perspective view illustrating an embodiment of a direction of a magnetic field generated by a first electromagnet and a second electromagnet of the disclosure.

FIG. 8 is a perspective view illustrating an embodiment of a direction of a magnetic field generated by a first permanent magnet, a second permanent magnet, a first electromagnet, and a second electromagnet of the disclosure.

FIG. 9 is a view illustrating an embodiment of a target module and a magnet bar of the disclosure.

FIG. 10 is a graph depicting an embodiment of a magnetic field intensity for each area according to the disclosure.

FIG. 11 is a cross-sectional view of an embodiment of magnet modules connected to a direct-current-to-direct-current (“DC”) power source and a plurality of resistors of the disclosure.

FIG. 12 is a graph depicting an embodiment of a magnetic field intensity for each area according to the disclosure.

FIG. 13 is a graph depicting an embodiment of a magnetic field intensity for each area according to the disclosure.

FIG. 14 illustrates an embodiment of a switching circuit according to the disclosure.

FIG. 15 is a plan view of an embodiment of magnet modules connected to a plurality of DC power sources of the disclosure.

FIG. 16 is a cross-sectional view of an embodiment of a sputtering apparatus of the disclosure.

FIG. 17 is a perspective view of an embodiment of a display device of the disclosure.

FIG. 18 is a block diagram of an embodiment of an electronic device.

FIG. 19 is schematic diagrams of embodiments of electronic devices.

### DETAILED DESCRIPTION

In the specification, the expression that a first component (or area, layer, part, portion, etc.) is “on”, “connected with”, or “coupled with” a second component means that the first component is directly on, connected with, or coupled with the second component or means that a third component is interposed therebetween.

The same reference numerals refer to the same components. Furthermore, in drawings, the thickness, ratio, and dimension of components are exaggerated for effectiveness of description of technical contents. The term “and/or” includes one or more combinations in each of which associated elements are defined.

Although the terms “first”, “second”, etc. may be used to describe various components, the components should not be construed as being limited by the terms. The terms are used only for the purpose of distinguishing one component, part, area, layer, or portion from another component, part, area, layer, or portion. For example, without departing from the scope of the disclosure, a first component, a first part, a first area, a first layer, or a first portion may be referred to as a second component, a second part, a second area, a second layer, or a second portion, and similarly, a second component, a second part, a second area, a second layer, or a second portion may be referred to as a first component, a first part, a first area, a first layer, or a first portion. The articles “a,” “an,” and “the” are singular in that they have a single referent, but the use of the singular form in the specification should not preclude the presence of more than one referent.

Also, the terms “under”, “below”, “on”, “above”, and the like are used to describe the correlation of components illustrated in drawings. The terms are relative concepts, and are described with respect to directions indicated in the drawings.

It will be understood that the terms “include”, “comprise”, “have”, and the like specify the presence of features, numbers, steps, operations, elements, or components, described in the specification, or a combination thereof, not precluding the presence or additional possibility of one or more other features, numbers, steps, operations, elements, or components or a combination thereof.

Unless otherwise defined, all terms (including technical terms and scientific terms) used in the specification have the same meaning as commonly understood by one skilled in the art to which the disclosure belongs. Furthermore, the terms, such as the terms defined in dictionaries, which are generally used, should be construed to coincide with the context meanings of the related technologies, and are not construed as ideal or excessively formal meanings unless explicitly defined in the disclosure.

Hereinafter, embodiments of the disclosure will be described with reference to accompanying drawings.

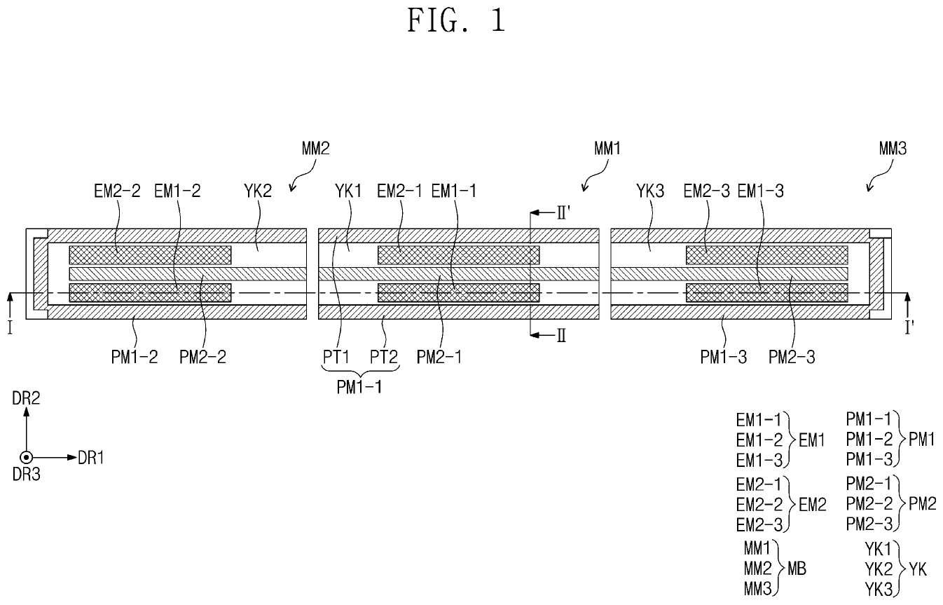

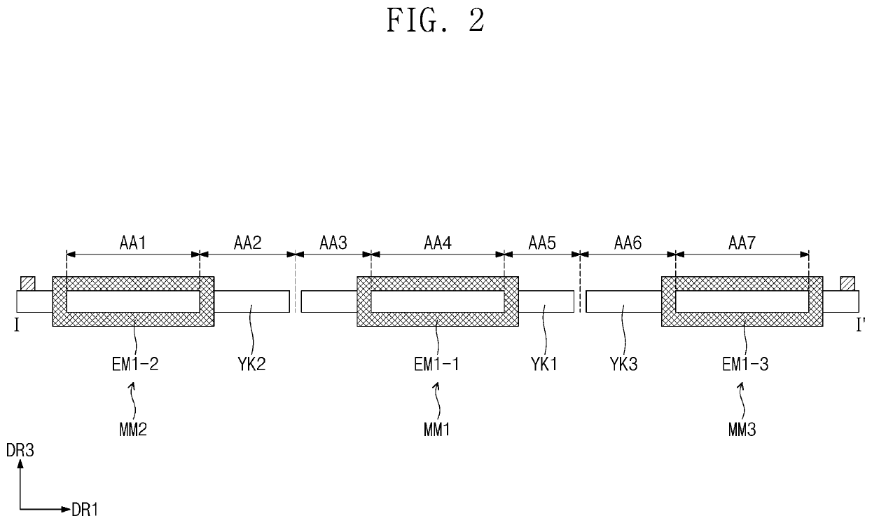

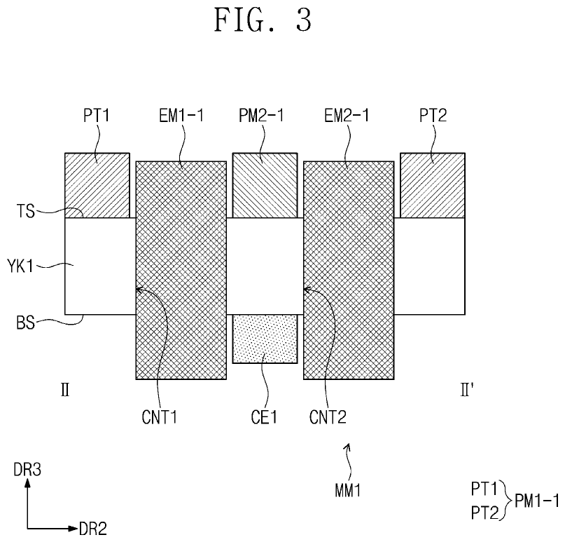

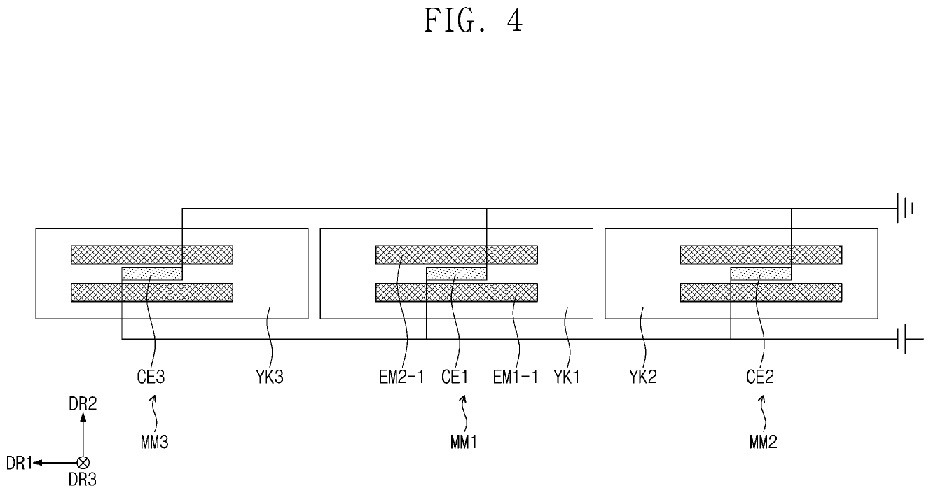

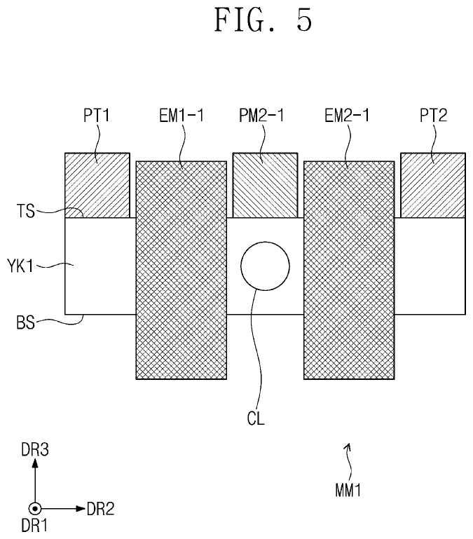

FIG. 1 is a plan view of an embodiment of a magnet bar of the disclosure. FIG. 2 is a cross-sectional view of the magnet bar taken along cutting line I-I′ of FIG. 1. FIG. 3 is a cross-sectional view of the magnet bar taken along cutting line II-II′ of FIG. 1. FIG. 4 is a cross-sectional view of the magnet bar viewed from a rear side according to FIG. 1. FIG. 5 is a cross-sectional view of an embodiment of the magnet bar taken along cutting line II-II′ of FIG. 1 of the disclosure.

Referring to FIG. 1, a magnet bar MB may include a first magnet module MM1, a second magnet module MM2, and a third magnet module MM3. Each of the first to third magnet modules MM1 to MM3 may include a yoke YK, a first permanent magnet PM1, a second permanent magnet PM2, a first electromagnet EM1, and a second electromagnet EM2. That is, the first magnet module MM1 may include a first yoke YK1, a (1-1)-th permanent magnet PM1-1, a (2-1)-th permanent magnet PM2-1, a (1-1)-th electromagnet EM1-1, and a (2-1)-th electromagnet EM2-1, the second magnet module MM2 may include a second yoke YK2, a (1-2)-th permanent magnet PM1-2, a (2-2)-th permanent magnet PM2-2, a (1-2)-th electromagnet EM1-2, and a (2-2)-th electromagnet EM2-2, and the third magnet module MM3 may include a third yoke YK3, a (1-3)-th permanent magnet PM1-3, a (2-3)-th permanent magnet PM2-3, a (1-3)-th electromagnet EM1-3, and a (2-3)-th electromagnet EM2-3.

The first to third magnet modules MM1 to MM3 may be arranged in a first direction DR1. The first magnet module MM1 may be disposed between the second magnet module MM2 and the third magnet module MM3 in the first direction DR1. However, the disclosure is not limited thereto. Although FIG. 1 illustrates, as one of the embodiments, the first magnet module MM1 that is disposed between the second magnet module MM2 and the third magnet module MM3 to describe an embodiment of the disclosure, a plurality of magnet modules may be disposed between the second magnet module MM2 and the third magnet module MM3 in an embodiment of the disclosure.

The second magnet module MM2 and the third magnet module MM3 include configurations that are similar to that of the first magnet module MM1. Accordingly, hereinafter, the first magnet module MM1 will be mainly described, and a description of the second magnet module MM2 and the third magnet module MM3 will be replaced with the description for the first magnet module MM1. For the second magnet module MM2 and the third magnet module MM3, differences from the first magnet module MM1 will be mainly described.

The (1-1)-th permanent magnet PM1-1 may include a first part PT1 and a second part PT2. The first part PT1 and the second part PT2 may extend in the first direction DR1 and may be spaced apart from each other in a second direction DR2. The (2-1)-th permanent magnet PM2-1 may extend in the first direction DR1. The (2-1)-th permanent magnet PM2-1 may be disposed between the first part PT1 and the second part PT2 in the second direction DR2. The (1-1)-th permanent magnet PM1-1 and the (2-1)-th permanent magnet PM2-1 may be magnets having different polarities. In an embodiment of the disclosure, the (1-1)-th permanent magnet PM1-1 may be an S-pole magnet and the (2-1)-th permanent magnet PM2-1 may be an N-pole magnet. The (1-1)-th permanent magnet PM1-1 and the (2-1)-th permanent magnet PM2-1 may be anisotropic or isotropic sintered magnets mainly composed of neodymium, iron, and boron, samarium-cobalt magnets, or ferrite magnets.

The (1-1)-th electromagnet EM1-1 and the (2-1)-th electromagnet EM2-1 may include or consist of a conductive material. In an embodiment, the (1-1)-th electromagnet EM1-1 and the (2-1)-th electromagnet EM2-1 may be wires including or consisting of aluminum or copper having a predetermined thickness, for example. Furthermore, an insulating material may be coated on the surfaces of the (1-1)-th electromagnet EM1-1 and the (2-1)-th electromagnet EM2-1. In an embodiment, an insulating material, such as enamel, polymer, or Teflon, may be coated on the surfaces of the (1-1)-th electromagnet EM1-1 and the (2-1)-th electromagnet EM2-1, for example.

In a plan view, the (1-1)-th electromagnet EM1-1 and the (2-1)-th electromagnet EM2-1 may extend in the first direction DR1 and may be spaced apart from each other in the second direction DR2. In an embodiment of the disclosure, the (1-1)-th electromagnet EM1-1 may be disposed between the first part PT1 of the (1-1)-th permanent magnet PM1-1 and the (2-1)-th permanent magnet PM2-1 in the second direction DR2, and the (2-1)-th electromagnet EM2-1 may be disposed between the second part PT2 of the (1-1)-th permanent magnet PM1-1 and the (2-1)-th permanent magnet PM2-1 in the second direction DR2.

Referring to FIGS. 1 and 2, the first yoke YK1 may have a flat plate shape. The first yoke YK1 may include or consist of a magnetic material. In an embodiment, the first yoke YK1 may be a ferritic stainless steel, for example.

The (1-1)-th electromagnet EM1-1 and the (2-1)-th electromagnet EM2-1 may have a winding structure that is wound around the first yoke YK1. That is, upper sides of the (1-1)-th electromagnet EM1-1 and the (2-1)-th electromagnet EM2-1 may be disposed on the first yoke YK1, and lower sides of the (1-1)-th electromagnet EM1-1 and the (2-1)-th electromagnet EM2-1 may be disposed under the first yoke YK1. Side surfaces of the (1-1)-th electromagnet EM1-1 and the (2-1)-th electromagnet EM2-1 may pass through the first yoke YK1 in a third direction DR3.

When a voltage is applied to the (1-1)-th electromagnet EM1-1 and the (2-1)-th electromagnet EM2-1, a current flows, and a magnetic field may be formed depending on the winding structure of the (1-1)-th electromagnet EM1-1 and the (2-1)-th electromagnet EM2-1. Here, the intensity and direction of the magnetic field formed may be determined depending on a magnitude and direction of the current that flows through the (1-1)-th electromagnet EM1-1 and the (2-1)-th electromagnet EM2-1. The intensity of the magnetic field formed inside the first yoke YK1 by the (1-1)-th electromagnet EM1-1 and the (2-1)-th electromagnet EM2-1 wound around the first yoke YK1 may be determined according to Equation 1 below.

$$\\ B = \frac{μ N I}{L} \qquad [ Equation 1 ]$$

Here, B is an intensity of the magnetic field, μ is a magnetic permeability of the first yoke YK1, N/L is the number of windings per unit length of the (1-1)-th electromagnet EM1-1 and the (2-1)-th electromagnet EM2-1, and “I” is a magnitude of the current.

The intensity of the magnetic field may also be determined depending on a thickness of the wire that forms the (1-1)-th electromagnet EM1-1 and the (2-1)-th electromagnet EM2-1. In an embodiment, when wires that forms the (1-1)-th electromagnet EM1-1 and the (2-1)-th electromagnet EM2-1 are thin, the number of windings may increase, and the intensity of the magnetic field that is formed by the (1-1)-th electromagnet EM1-1 and the (2-1)-th electromagnet EM2-1 may increase, for example. However, in this case, a resistance of the (1-1)-th electromagnet EM1-1 and the (2-1)-th electromagnet EM2-1 themselves may increase, so that heat may be generated. Accordingly, an appropriate thickness of the wire that forms the (1-1)-th electromagnet EM1-1 and the (2-1)-th electromagnet EM2-1 may be selected depending on a desired magnetic field intensity, a space between a (1-1)-th permanent magnet PM1-1 and a (2-1)-th permanent magnet PM2-1, and a cooling efficiency.

Cross-sectional arrangements of the first electromagnet EM1 and the second electromagnet EM2 in the first to third magnet modules MM1 to MM3 may be classified into first to seventh areas AA1 to AA7. In an embodiment, the second magnet module MM2 may be classified into a first area AA1 and a second area AA2 in the first direction DR1, for example. The first area AA1 may be an internal area of the (1-2)-th electromagnet EM1-2 and the (2-2)-th electromagnet EM2-2 in the second magnet module MM2, and the second area AA2 may be an external area of the (1-2)-th electromagnet EM1-2 and the (2-2)-th electromagnet EM2-2 in the second magnet module MM2. The first magnet module MM1 may be divided into a third area AA3, a fourth area AA4, and a fifth area AA5 in the first direction DR1. The fourth area AA4 may be an internal area of the (1-1)-th electromagnet EM1-1 and the (2-1)-th electromagnet EM2-1 in the first magnet module MM1, and the third area AA3 and the fifth area AA5 may be external areas of the (1-1)-th electromagnet EM1-1 and the (2-1)-th electromagnet EM2-1 in the first magnet module MM1. The third area AA3 may be an area between the (1-1)-th electromagnet EM1-1 and the (1-2)-th electromagnet EM1-2, and the fifth area AA5 may be an area between the (1-1)-th electromagnet EM1-1 and the (1-3)-th electromagnet EM1-3. The third magnet module MM3 may be divided into a sixth area AA6 and a seventh area AA7 in the first direction DR1. The sixth area AA6 may be an external area of (1-3)-th electromagnet EM1-3 and the (2-3)-th electromagnet EM2-3 in the third magnet module MM3, and the seventh area AA7 may be an internal area of the (1-3)-th electromagnet EM1-3 and the (2-3)-th electromagnet EM2-3 in the third magnet module MM3. In an embodiment of the disclosure, the internal areas of the first electromagnet EM1 and the second electromagnet EM2 may be internal areas of closed loop that is formed while the first electromagnet EM1 and the second electromagnet EM2 are wound around the yoke YK.

In an embodiment of the disclosure, the first, fourth, and seventh areas AA1, AA4, and AA7 may be internal areas of the first electromagnet EM1 and the second electromagnet EM2 in a cross-section, and the second, third, fifth, and sixth areas AA2, AA3, AA5, and AA6 may be external areas of the first electromagnet EM1 and the second electromagnet EM2 in the cross-section. Because a magnetic field may be formed by current that flows through the first electromagnet EM1 and the second electromagnet EM2, an intensity of the magnetic field in the first, fourth, and seventh areas AA1, AA4, and AA7, which are internal areas of the first electromagnet EM1 and the second electromagnet EM2 may differ from the intensity of the magnetic field in the second, third, fifth, and sixth areas AA2, AA3, AA5, and AA6. The detailed description thereof will be described later.

Referring to FIGS. 1 and 3, the (1-1)-th permanent magnet PM1-1 and the (2-1)-th permanent magnet PM2-1 may be disposed on a top surface TS of the first yoke YK1. The first yoke YK1 may control a path of a magnetic field formed by the (1-1)-th permanent magnet PM1-1 and the (2-1)-th permanent magnet PM2-1, and a magnetic field formed by the (1-1)-th electromagnet EM1-1 and the (2-1)-th electromagnet EM2-1.

The (1-1)-th electromagnet EM1-1 may be wound around a portion of the first yoke YK1 in a coil form between the first part PT1 of the (1-1)-th permanent magnet PM1-1 and the (2-1)-th permanent magnet PM2-1, and the (2-1)-th electromagnet EM2-1 may be wound around a portion of the first yoke YK1 in a coil form between the second part PT2 of the (1-1)-th permanent magnet PM1-1 and the (2-1)-th permanent magnet PM2-1. A first contact hole CNT1 and a second contact hole CNT2 that pass through the first yoke YK1 in the third direction DR3 may be defined in the first yoke YK1. The (1-1)-th electromagnet EM1-1 may be wound around the first yoke YK1 through the first contact hole CNT1, and the (2-1)-th electromagnet EM2-1 may be wound around the first yoke YK1 through the second contact hole CNT2.

Referring to FIGS. 3 and 4, the first to third magnet modules MM1 to MM3 may further include cooling elements CE1 to CE3 that are disposed on bottom surfaces BS of the first to third yokes YK1 to YK3, respectively. In an embodiment of the disclosure, the cooling elements CE1 to CE3 may be Peltier elements. Cooling power of the cooling elements CE1 to CE3 may be set according to the following Equation 2.

$$P > \frac{{( V max )}^{2}}{R} \qquad [ Equation 2 ]$$

Here, “P” is the cooling power of the cooling elements CE1 to CE3, Vmax is a voltage that reaches a preset temperature when a direct-current-to-direct-current (“DC”) voltage is applied to the (1-1)-th electromagnet EM1-1 and the (2-1)-th electromagnets EM2-1, and “R” is resistances of the (1-1)-th electromagnet EM1-1 and the (2-1)-th electromagnet EM2-1 themselves.

While current flows through the (1-1)-th electromagnet EM1-1 and the (2-1)-th electromagnet EM2-1, heat may be generated in the (1-1)-th electromagnet EM1-1 and the (2-1)-th electromagnet EM2-1. Because the heat may cause demagnetization of the first permanent magnet PM1 (refer to FIG. 1) and the second permanent magnet PM2 (refer to FIG. 1), the heat generated by the (1-1)-th electromagnet EM1-1 and the (2-1)-th electromagnet EM2-1 may be controlled by the cooling elements CE1 to CE3. The cooling elements CE1 to CE3 may be connected to a power source that provides a constant voltage, and each of the cooling elements CE1 to CE3 may be connected in parallel to each other. By using a thermoelectric effect of absorbing heat on one side and emitting heat on an opposite side of each cooling element CE1 to CE3, the heat generated by the (1-1)-th electromagnet EM1-1 and the (2-1)-th electromagnet EM2-1 may be controlled. Accordingly, performance degradation of the first to third magnet modules MM1 to MM3 may be prevented and reliability may be improved.

Referring to FIG. 5, in an embodiment of the disclosure, the first magnet module MM1 may include a cooling water line CL instead of the cooling elements CE1 to CE3 (refer to FIG. 3). While current flows through the (1-1)-th electromagnet EM1-1 and the (2-1)-th electromagnet EM2-1, the cooling water line CL may control the heat generated in the (1-1)-th electromagnet EM1-1 and the (2-1)-th electromagnet EM2-1. The cooling water line CL may be disposed to pass through the first yoke YK1 in the first direction DR1. However, the disclosure is not limited thereto, and the cooling water line CL may also be disposed on the bottom surface BS of the first yoke YK1.

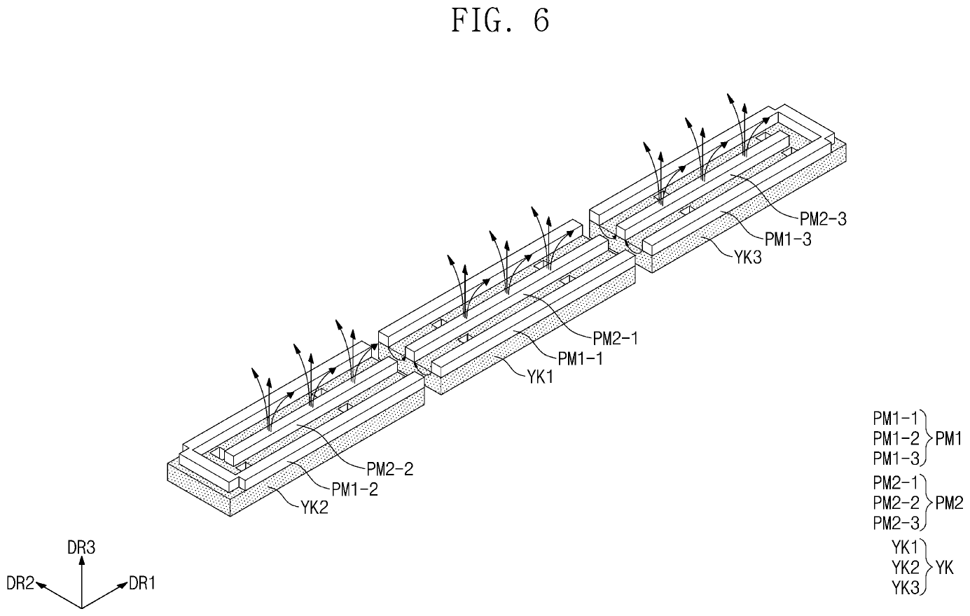

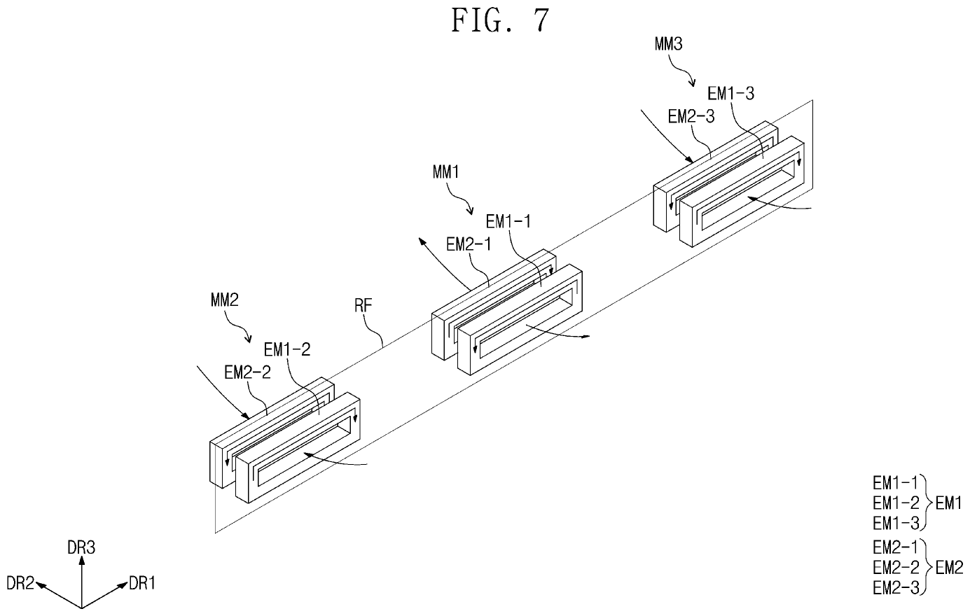

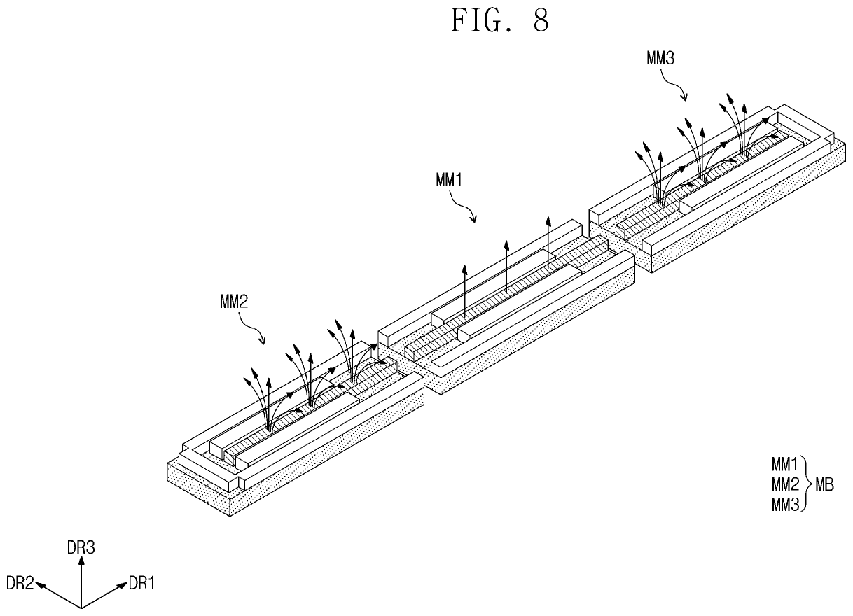

FIG. 6 is a perspective view illustrating a direction of a magnetic field generated by a first permanent magnet and a second permanent magnet according to a comparative example. FIG. 7 is a perspective view illustrating an embodiment of a direction of a magnetic field generated by a first electromagnet and a second electromagnet of the disclosure. FIG. 8 is a perspective view illustrating an embodiment of a direction of a magnetic field generated by a first permanent magnet, a second permanent magnet, a first electromagnet, and a second electromagnet of the disclosure.

In FIG. 6, the components included in the magnet bar MB (refer to FIG. 8) except for the first electromagnet EM1 (refer to FIG. 7) and the second electromagnet EM2 (refer to FIG. 7) are illustrated for explaining a magnetic field generated by the first permanent magnet PM1 and the second permanent magnet PM2. Referring to FIG. 6, the first permanent magnet PM1 and the second permanent magnet PM2 may be attached on the yoke YK. A magnetic field may be formed by the first permanent magnet PM1 and the second permanent magnet PM2. Because the yoke YK is magnetizable, the magnetic field formed by the first permanent magnet PM1 and the second permanent magnet PM2 may be transferred through an interior of the yoke YK. The direction of the magnetic field formed by the first permanent magnet PM1 and the second permanent magnet PM2 may be a direction from the first permanent magnet PM1 toward the second permanent magnet PM2 in the interior of the yoke YK, and a direction that exits the second permanent magnet PM2 outside the yoke YK.

FIG. 7 illustrates only the first electromagnet EM1 and the second electromagnet EM2, among the components included in the magnet bar MB (refer to FIG. 8) for explaining a magnetic field generated by the first electromagnet EM1 and the second electromagnet EM2.

Referring to FIGS. 6, 7, and 8, a direction, in which the first electromagnet EM1 is wound around the yoke YK, may be opposite to a direction, in which the second electromagnet EM2 is wound around the yoke. In an embodiment, a first magnet module MM1 may include a (1-1)-th electromagnet EM1-1 and a (2-1)-th electromagnet EM2-1, and the (1-1)-th electromagnet EM1-1 may be wound around a first yoke YK1 in a counterclockwise direction, and the (2-1)-th electromagnet EM2-1 may be wound around the first yoke YK1 in a clockwise direction, for example. A second magnet module MM2 may include a (1-2)-th electromagnet EM1-2 and a (2-2)-th electromagnet EM2-2, and the (1-2)-th electromagnet EM1-2 may wind a second yoke YK2 in a clockwise direction, and the (2-2)-th electromagnet EM2-2 may wind the second yoke YK2 in a counterclockwise direction. A third magnet module MM3 may include a (1-3)-th electromagnet EM1-3 and a (2-3)-th electromagnet EM2-3, and the (1-3)-th electromagnet EM1-3 may be wound around a third yoke YK3 in a clockwise direction, and the (2-3)-th electromagnet EM2-3 may be wound around the third yoke YK3 in a counterclockwise direction. In an embodiment of the disclosure, the first electromagnet EM1 and the second electromagnet EM2 may be wound around the yoke YK in a quadrangular shape, e.g., rectangular shape in a cross-section.

Depending on a direction, in which the first electromagnet EM1 and the second electromagnet EM2 are wound around the yoke YK, a direction of a current that flows through the first electromagnet EM1 and the second electromagnet EM2 may be determined. With respect to the direction of the current that flows through the first electromagnet EM1 and the second electromagnet EM2, a magnetic field having a predetermined direction may be formed around the first electromagnet EM1 and the second electromagnet EM2. When the first electromagnet EM1 and the second electromagnet EM2 have a quadrangular shape, e.g., rectangular shape in a cross-section, a magnetic field having a predetermined direction may be formed in interiors of the first electromagnet EM1 and the second electromagnet EM2. In an embodiment, when the first electromagnet EM1 and the second electromagnet EM2 are wound around the yoke YK in a clockwise direction, the magnetic field may be formed in a second direction DR2, and when the first electromagnet EM1 and the second electromagnet EM2 are wound around the yoke YK in a counterclockwise direction, the magnetic field may be formed in a direction that is opposite to the second direction DR2, for example.

In the first magnet module MM1, the (1-1)-th electromagnet EM1-1 is wound around the first yoke YK1 in a counterclockwise direction, and the (2-1)-th electromagnet EM2-1 is wound around the first yoke YK1 in a clockwise direction, so that a magnetic field formed by the (1-1)-th electromagnet EM1-1 and the (2-1)-th electromagnet EM2-1 may be formed in a direction that exits a reference plane RF. Here, the reference plane RF is an imaginary plane that is defined as being parallel to the first direction DR1 and the third direction DR3 between the first electromagnet EM1 and the second electromagnet EM2.

In the second magnet module MM2, the (1-2)-th electromagnet EM1-2 is wound around the second yoke YK2 in a clockwise direction, and the (2-2)-th electromagnet EM2-2 is wound around the second yoke YK2 in a counterclockwise direction, so that a magnetic field formed by the (1-2)-th electromagnet EM1-2 and the (2-2)-th electromagnet EM2-2 may be formed in a direction toward the reference plane RF.

In the third magnet module MM3, the (1-3)-th electromagnet EM1-3 is wound around the third yoke YK3 in a clockwise direction, and the (2-3)-th electromagnet EM2-3 is wound around the third yoke YK3 in a counterclockwise direction, so that a magnetic field formed by the (1-3)-th electromagnet EM1-3 and the (2-3)-th electromagnet EM2-3 may be formed in a direction toward the reference plane RF.

Referring to FIGS. 7 and 8, the magnetic field formed by the first electromagnet EM1 and the second electromagnet EM2 may influence the magnetic field formed by the first permanent magnet PM1 and the second permanent magnet PM2. In an embodiment, in the first magnet module MM1, the magnetic field formed by the (1-1)-th electromagnet EM1-1 and the (2-1)-th electromagnet EM2-1 is in a direction that exits the reference plane RF, so that the magnetic field formed by the (1-1)-th permanent magnet PM1-1 and the (2-1)-th permanent magnet PM2-1 may be offset by the (1-1)-th electromagnet EM1-1 and the (2-1)-th electromagnet EM2-1, and the intensity of the magnetic field may be reduced, for example. In the second magnet module MM2, the magnetic field formed by the (1-2)-th electromagnet EM1-2 and the (2-2)-th electromagnet EM2-2 is in a direction toward the reference plane RF, so that the magnetic field formed by the (1-2)-th permanent magnet PM1-2 and the (2-2)-th permanent magnet PM2-2 may be reinforced by the (1-2)-th electromagnet EM1-2 and the (2-2)-th electromagnet EM2-2, and the intensity of the magnetic field may be increased. In the third magnet module MM3, the magnetic field formed by the (1-3)-th electromagnet EM1-3 and the (2-3)-th electromagnet EM2-3 is in a direction toward the reference plane RF, so that the magnetic field formed by the (1-3)-th permanent magnet PM1-3 and the (2-3)-th permanent magnet PM2-3 may be reinforced by the (1-3)-th electromagnet EM1-3 and the (2-3)-th electromagnet EM2-3, and the intensity may be increased. Accordingly, depending on a direction, in which the first electromagnet EM1 and the second electromagnet EM2 are wound around the yoke YK, the intensity of the magnetic field formed by the first permanent magnet PM1 and the second permanent magnet PM2 may be adjusted.

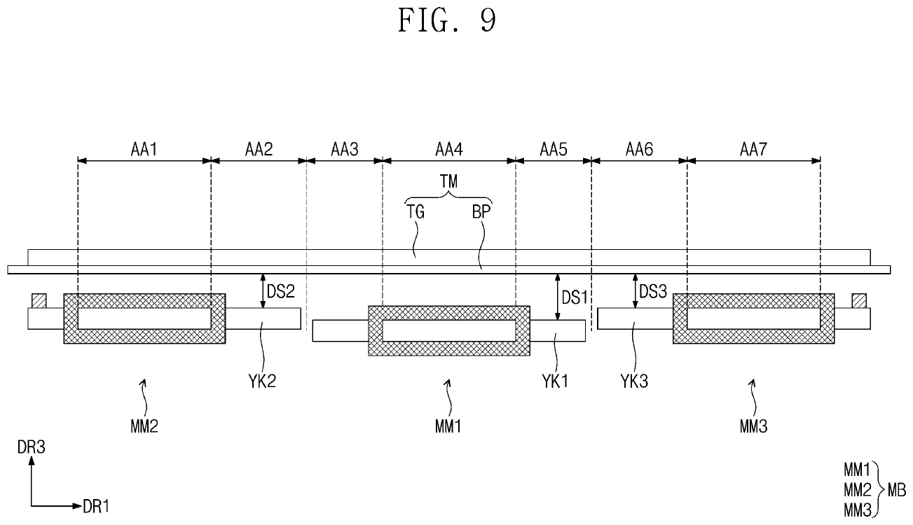

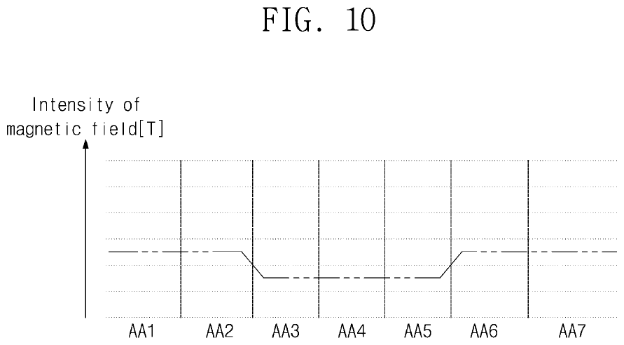

FIG. 9 is a view illustrating an embodiment of a target module and a magnet bar of the disclosure. FIG. 10 is a graph depicting an embodiment of a magnetic field intensity for each area according to the disclosure.

Referring to FIG. 9, a target module TM may be disposed on a magnet bar MB. The target module TM may include a target TG and a backing plate BP. The target TG may include Li, Ca, LiF/Ca, LiF/Al, Al, Mg, BaF, Ba, Ag or a compound or combination thereof (e.g., a combination of Ag and Mg), or may include a transparent metal oxide, such as indium tin oxide (“ITO”), indium zinc oxide (“IZO”), zinc oxide (ZnO), indium tin zinc oxide (“ITZO”), Mo, or Ti.

The backing plate BP may be disposed between the magnet bar MB and the target TG. The target TG may be fixed to one surface of the backing plate BP. The backing plate BP may fix the target TG.

The target module TM may be spaced apart from the magnet bar MB by a predetermined distance. A first magnet module MM1 may have a first distance DS1 from the target module TM, a second magnet module MM2 may have a second distance DS2 from the target module TM, and a third magnet module MM3 may have a third distance DS3 from the target module TM. The first to third distances DS1 to DS3 may be defined as distances from the backing plate BP to the yokes YK1, YK2, and YK3. At least one of the first to third distances DS1 to DS3 may differ from remaining (the other) distances. In an embodiment, the first distance DS1 may be greater than the second distance DS2 and the third distance DS3, and the second distance DS2 and the third distance DS3 may be equal to each other, for example.

Referring to FIGS. 9 and 10, magnetic field intensities [T] may vary depending on areas AA1 to AA7. The areas AA1 to AA7 illustrated in FIG. 10 correspond to the first to seventh areas AA1 to AA7 described with reference to FIG. 2. Here, the intensity of a magnetic field may refer to an intensity of the magnetic field in an area that overlaps with the second permanent magnet PM2 (refer to FIG. 1), among the area on the target TG. FIG. 10 illustrates the intensities of the magnetic fields formed by the first permanent magnet PM1 (refer to FIG. 1) and the second permanent magnet PM2 (refer to FIG. 1), which are not influenced by the magnetic fields formed by the first electromagnet EM1 (refer to FIG. 1) and the second electromagnet EM2 (refer to FIG. 1). Because the first magnet module MM1 is more distant from the target module TM compared to the second and third magnet modules MM2 and MM3, the magnetic field intensities generated by the first permanent magnet PM1 (refer to FIG. 1) and the second permanent magnet PM2 (refer to FIG. 1) in the area, in which the first magnet module MM1 is disposed, may be decreased. That is, the intensities of the magnetic fields in the third, fourth, and fifth areas AA3, AA4, and AA5 may be lower than the intensities of the magnetic fields in the first, second, sixth, and seventh areas AA1, AA2, AA6, and AA7.

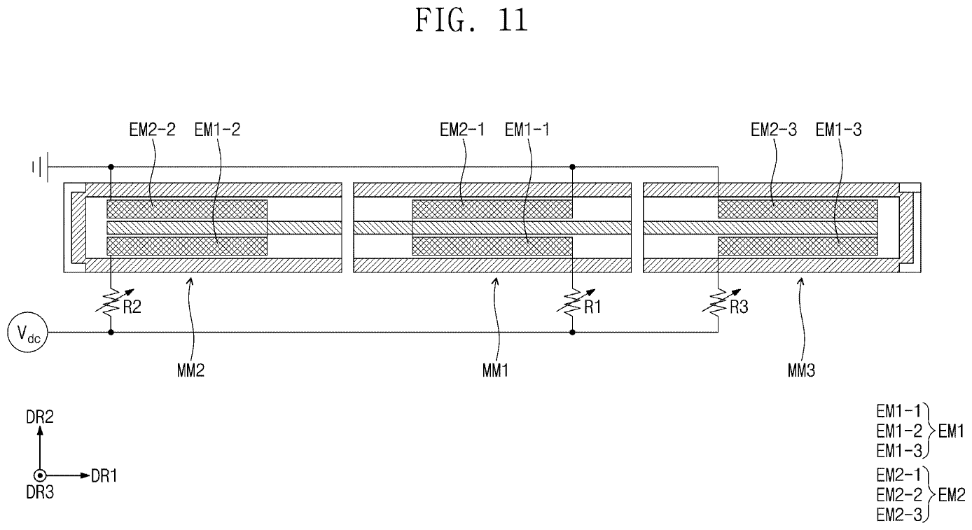

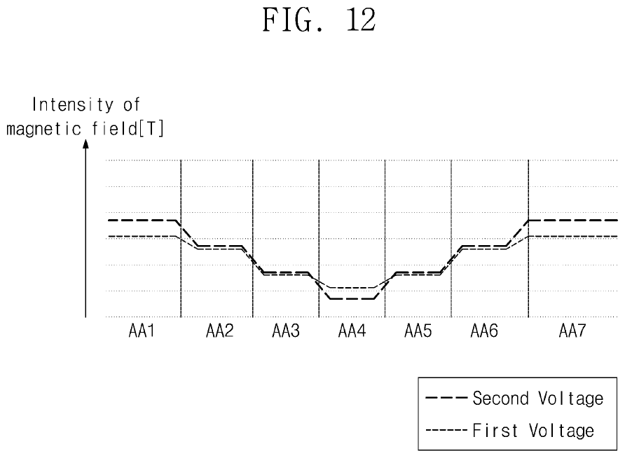

FIG. 11 is a cross-sectional view of an embodiment of magnet modules connected to a DC power source and a plurality of resistors of the disclosure. FIG. 12 is a graph depicting an embodiment of a magnetic field intensity for each area according to the disclosure.

Referring to FIG. 11, the magnet modules MM1, MM2, and MM3 may be connected to each other in parallel. The (1-1)-th electromagnet EM1-1 and the (2-1)-th electromagnet EM2-1 may be connected to each other in series, the (1-2)-th electromagnet EM1-2 and the (2-2)-th electromagnet EM2-2 may be connected to each other in series, and the (1-3)-th electromagnet EM1-3 and the (2-3)-th electromagnet EM2-3 may be connected to each other in series. The magnet modules MM1, MM2, and MM3 may be electrically connected to a DC power source Vdc. That is, the magnet modules MM1, MM2, and MM3 may receive electric power from a common DC power source Vdc, and a current may flow through the first electromagnet EM1 and the second electromagnet EM2. Accordingly, a magnetic field may be formed by the first electromagnet EM1 and the second electromagnet EM2.

The magnet bar MB may further include a plurality of resistors R1, R2, and R3 that are connected to the magnet modules MM1, MM2, and MM3, respectively. A first resistor R1 may be connected to the (1-1)-th electromagnet EM1-1 and the (2-1)-th electromagnet EM2-1, a second resistor R2 may be connected to the (1-2)-th electromagnet EM1-2 and the (2-2)-th electromagnet EM2-2, and a third resistor R3 may be connected to the (1-3)-th electromagnet EM1-3 and the (2-3)-th electromagnet EM2-3. Each of the plurality of resistors R1, R2, and R3 may be a variable resistor. By adjusting the resistance values of the plurality of resistors R1, R2, and R3, a current that flows through the first electromagnet EM1 and the second electromagnet EM2 may be adjusted, and accordingly, the magnetic field intensity may be adjusted.

FIG. 12 illustrates, as one of the embodiments, intensities of magnetic fields when a first voltage and a second voltage are applied from the DC power source Vdc to the first and second electromagnets EM1 and EM2. Here, the intensity of a magnetic field may refer to an intensity of the magnetic field in an area that overlaps with the second permanent magnet PM2 (refer to FIG. 1), among the area on the target TG. In an embodiment, the resistance values of the plurality of resistors R1, R2, and R3 are the same.

Referring to FIGS. 11 and 12, when a first voltage is applied to the first and second electromagnets EM1 and EM2 from the DC power source Vdc, a magnetic field may be formed by the first and second electromagnets EM1 and EM2. Accordingly, the intensity of the magnetic field in the first area AA1 may be higher than the intensity of the magnetic field in the second area AA2, the intensity of the magnetic field in the fourth area AA4 may be lower than the intensity of the magnetic field in the third and fifth areas AA3 and AA5, and the intensity of the magnetic field in the seventh area AA7 may be higher than the intensity of the magnetic field in the sixth area AA6.

The first area AA1 may be an area, in which the (1-2)-th electromagnet EM1-2 and the (2-2)-th electromagnet EM2-2 of the second magnet module MM2 are disposed. A direction of a magnetic field formed by the (1-2)-th electromagnet EM1-2 and the (2-2)-th electromagnet EM2-2 may be the same as a direction of a magnetic field formed by the (1-2)-th permanent magnet PM1-2 and the (2-2)-th permanent magnet PM2-2. Accordingly, the magnetic field formed by the (1-2)-th electromagnet EM1-2 and the (2-2)-th electromagnet EM2-2 may increase an intensity of the magnetic field formed by the (1-2)-th permanent magnet PM1-2 and the (2-2)-th permanent magnet PM2-2.

The fourth area AA4 may be an area, in which the (1-1)-th electromagnet EM1-1 and the (2-1)-th electromagnet EM2-1 of the first magnet module MM1 are disposed. A direction of the magnetic field formed by the (1-1)-th electromagnet EM1-1 and the (2-1)-th electromagnet EM2-1 may be opposite to a direction of the magnetic field formed by the (1-1)-th permanent magnet PM1-1 and the (2-1)-th permanent magnet PM2-1. Accordingly, the magnetic field formed by the (1-1)-th electromagnet EM1-1 and the (2-1)-th electromagnet EM2-1 may decrease the intensity of the magnetic field formed by the (1-1)-th permanent magnet PM1-1 and the (2-1)-th permanent magnet PM2-1.

The seventh area AA7 may be an area, in which the (1-3)-th electromagnet EM1-3 and the (2-3)-th electromagnet EM2-3 of a third magnet module MM3 are disposed. A direction of the magnetic field formed by the (1-3)-th electromagnet EM1-3 and the (2-3)-th electromagnet EM2-3 may be the same as a direction of the magnetic field formed by the (1-3)-th permanent magnet PM1-3 and the (2-3)-th permanent magnet PM2-3. Accordingly, the magnetic field formed by the (1-3)-th electromagnet EM1-3 and the (2-3)-th electromagnet EM2-3 may increase an intensity of the magnetic field formed by the (1-3)-th permanent magnet PM1-3 and the (2-3)-th permanent magnet PM2-3.

In an embodiment of the disclosure, a second voltage that is greater than a first voltage may be applied to the first electromagnet EM1 and the second electromagnet EM2 by a DC power source Vdc. When a higher voltage is applied to the first electromagnet EM1 and the second electromagnet EM2, a stronger magnetic field may be generated by the first electromagnet EM1 and the second electromagnet EM2. That is, in the first area AA1, the intensity of the magnetic field may increase more when the second voltage is applied to the (1-2)-th electromagnet EM1-2 and the (2-2)-th electromagnet EM2-2 than when the first voltage is applied, in the fourth area AA4, the intensity of the magnetic field may decrease more when the second voltage is applied to the (1-1)-th electromagnet EM1-1 and the (2-1)-th electromagnet EM2-1 than when the first voltage is applied, and in the seventh area AA7, the intensity of the magnetic field may increase more when the second voltage is applied to the (1-3)-th electromagnet EM1-3 and the (2-3)-th electromagnet EM2-3 than when the first voltage is applied.

Because the second, third, fifth, and sixth areas AA2, AA3, AA5, and AA6 are internal areas of the first electromagnet EM1 and the second electromagnet EM2, the magnetic fields formed by the first electromagnet EM1 and the second electromagnet EM2 may not affect those areas. According to the disclosure, an intensity of a magnetic field in an internal area of the first electromagnet EM1 and the second electromagnet EM2 in a cross-section may be adjusted.

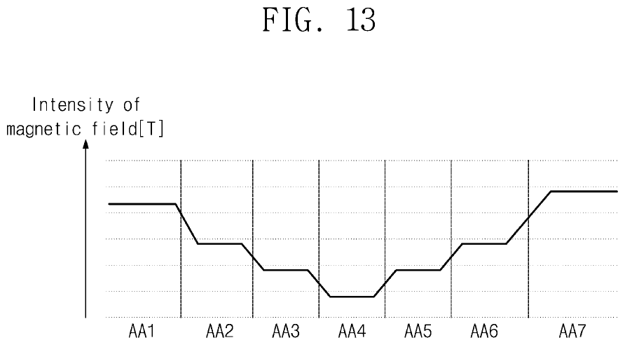

FIG. 13 is a graph depicting an embodiment of a magnetic field intensity for each area according to the disclosure.

Referring to FIGS. 11 and 13, in an embodiment of the disclosure, the first to third resistors R1 to R3 may have different resistance values from each other. That is, the graph depicted in FIG. 13 is a graph that represents intensities of magnetic fields depending on resistance values of the first resistor R1, the second resistor R2, and the third resistor R3. Here, the intensity of a magnetic field may refer to an intensity of the magnetic field in an area that overlaps with the second permanent magnet PM2 (refer to FIG. 1), among the area on the target TG.

In an embodiment of the disclosure, the resistance value of the first resistor R1 may be greater than the resistance value of the second resistor R2, and the resistance value of the second resistor R2 may be greater than the resistance value of the third resistor R3. Here, the first resistor R1 may have the same resistance value as that of the resistors R1, R2, and R3 described with reference to FIG. 12. That is, the magnetic field in the fourth area AA4 may be the same as the magnetic field in the fourth area AA4 described with reference to FIG. 12. Because the resistance value of the second resistor R2 is smaller than the resistance value of the first resistor R1, the intensity of the magnetic field in the first area AA1 may be greater than the intensity of the magnetic field in the first area AA1 described with reference to FIG. 12. Because the resistance value of the third resistor R3 is smaller than the resistance value of the second resistor R2, the intensity of the magnetic field in the seventh area AA7 may be greater than the intensity of the magnetic field in the seventh area AA7 described with reference to FIG. 12. Furthermore, the intensity of the magnetic field in the seventh area AA7 may be greater than the intensity of the magnetic field in the first area AA1.

In this way, according to the disclosure, the first to third resistors R1 to R3 may be connected to the first to third magnet modules MM1 to MM3, respectively, so that the magnetic field intensity may be independently adjusted for each of the first to third magnet modules MM1 to MM3.

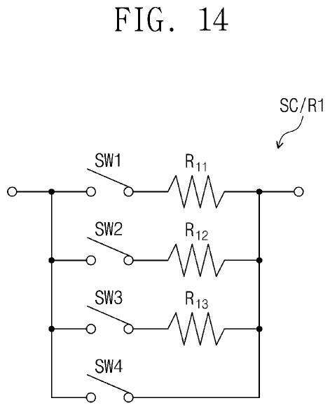

FIG. 14 illustrates an embodiment of a switching circuit according to the disclosure.

Referring to FIGS. 11 and 14, each of the plurality of resistors R1, R2, and R3 may be replaced with a switching circuit SC. That is, the magnet bar MB (refer to FIG. 1) may further include a plurality of switching circuits SC that are connected to the first to third magnet modules MM1, MM2, and MM3. In FIG. 14, a switching circuit SC that may replace the first resistor R1 is illustrated as one of the embodiments.

The switching circuit SC may be connected to a plurality of switching elements SW1, SW2, SW3, and SW4 and a plurality of sub-resistors R₁₁, R₁₂, and R₁₃. The first switching element SW1 may be connected to a first sub-resistor R₁₁ in series, the second switching element SW2 may be connected to a second sub-resistor R₁₂ in series, and the third switching element SW3 may be connected to a third sub-resistor R₁₃ in series. The fourth switching element SW4 may not be connected to any resistor in series.

At least one of the plurality of switching elements SW1, SW2, SW3, and SW4 may be turned on, and a resistance of the resistor connected to the turned-on switching elements may be the overall resistance of the switching circuit SC. In an embodiment, when the first switching element SW1 is turned on and the second, third, and fourth switching elements SW2, SW3, and SW4 are turned off, the overall resistance of the switching circuit SC may be the resistance of the first sub-resistor R₁₁, for example. In addition, when the second and third switching elements SW2 and SW3 are turned on and the first and fourth switching elements SW1 and SW4 are turned off, the overall resistance of the switching circuit SC may be a resistance, in which the second and third sub-resistors R₁₂ and R₁₃ are connected thereto in parallel. Furthermore, when the fourth switching element SW4 is turned on and the first, second, and third switching elements SW1, SW2, and SW3 are turned off, the overall resistance of the switching circuit SC may be zero.

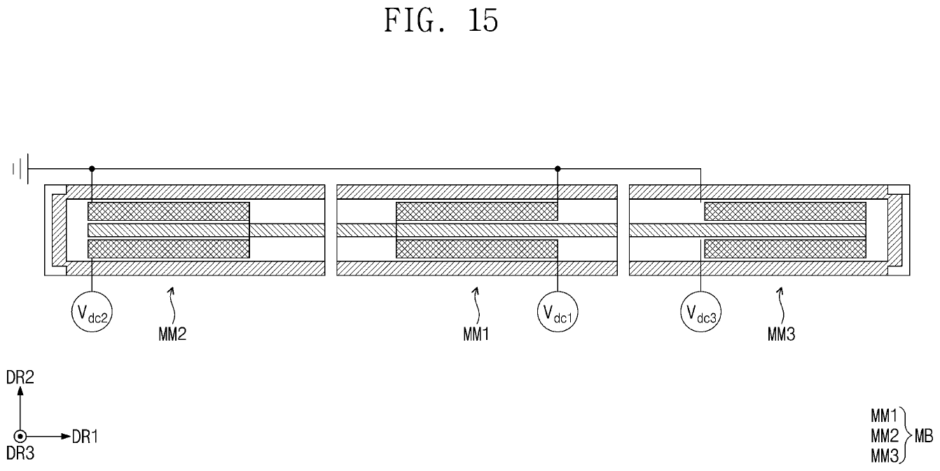

FIG. 15 is a plan view of an embodiment of magnet modules connected to a plurality of DC power sources of the disclosure.

Referring to FIG. 15, the magnet bar MB may include a plurality of DC power sources Vdc1, Vdc2, and Vdc3 instead of the plurality of resistors R1, R2, and R3 (refer to FIG. 11). The first DC power source Vdc1 may be connected to the first magnet module MM1, the second DC power source Vdc2 may be connected to the second magnet module MM2, and the third DC power source Vdc3 may be connected to the third magnet module MM3. In this way, the first to third DC power sources Vdc1 to Vdc3 may be connected to the first to third magnet modules MM1 to MM3, respectively, so that the magnetic field intensity may be independently adjusted for each of the first to third magnet modules MM1 to MM3 by adjusting the first to third DC power sources Vdc1 to Vdc3.

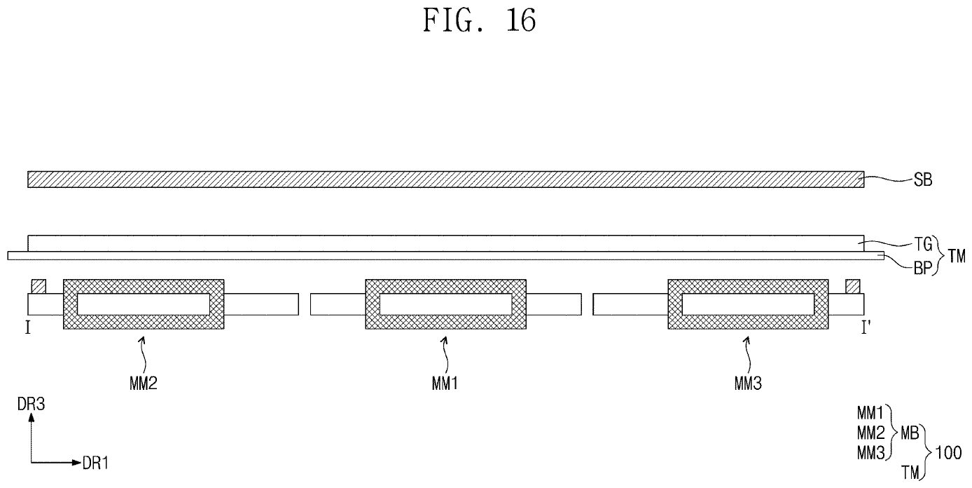

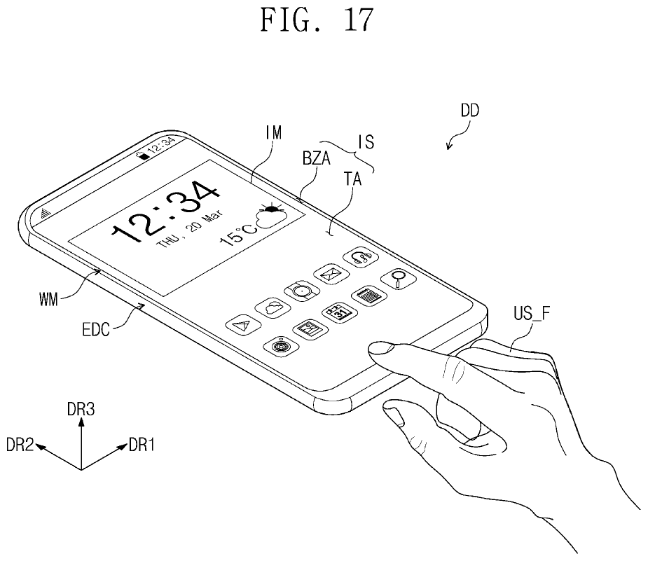

FIG. 16 is a cross-sectional view of an embodiment of a sputtering apparatus of the disclosure. FIG. 17 is a perspective view of an embodiment of a display device of the disclosure.

Referring to FIG. 16, a sputtering apparatus 100 may include a magnet bar MB and a target module TM. The magnet bar MB and the target module TM applied to the sputtering apparatus 100 may correspond to the magnet bar MB and the target module TM according to the above-described embodiment. A substrate SB may be disposed on the target module TM.

The sputtering apparatus 100 may further include a chamber (not illustrated). The magnet bar MB, the target module TM, and the substrate SB are disposed in the chamber. After the chamber vacuumed, an inert gas, such as argon (“AR”), may be introduced into the chamber. Thereafter, when a voltage is applied to the target TG, electrons are emitted from a surface of the target TG, and the emitted electrons may be affected by a magnetic field formed by the magnet bar MB. The electrons collide with and ionize the inert gas, so that plasma is formed near the target TG. Due to the magnetic field formed by the magnet bar MB, the electrons may collide more frequently with the inert gas, and thus, the sputtering efficiency may be increased. The plasma may be stably maintained near the target TG. The ions may collide with the surface of the target TG. Accordingly, atoms of the target TG may be ejected and deposited onto the substrate SB, so that a thin film may be formed on the substrate SB as a material of the target TG.

Through the sputtering apparatus 100, a display device DD as illustrated in FIG. 17 may be provided. Several thin films may be formed on the substrate SB to provide the display device DD. In an embodiment, through the sputtering apparatus 100, an electrode layer or a structure, such as a thin-film transistor (“TFT”), included in the display device DD may be formed, for example.

FIG. 17 is a perspective view of an embodiment of a display device of the disclosure.

Referring to FIG. 17, a display device DD in an embodiment of the disclosure may have a shape of a rectangle having short sides that are parallel to a first direction DR1 and long sides that are parallel to a second direction DR2 that crosses the first direction DR1. However, the disclosure is not limited thereto. In an embodiment, the display device DD may have various shapes, such as a circle and a polygon, for example.

The display device DD may be a device that is activated in response to an electrical signal. The display device DD may include embodiments. In an embodiment, the display device DD may be applied to an electronic device, such as a smart watch, a tablet personal computer (“PC”), a laptop computer, a computer, a smart television, or the like, for example.

Hereinafter, a normal direction that is substantially perpendicular to a plane that is defined by the first direction DR1 and the second direction DR2 is defined as a third direction DR3. In the specification, the meaning of “in a plan view” may mean “when viewed in the third direction DR3”.

A top surface of the display device DD may be defined as a display surface IS, and may be parallel to a plane that is defined by the first direction DR1 and the second direction DR2. Images IM generated by the display device DD may be provided to a user through the display surface IS.

The display surface IS may be divided into a transmission area TA and a bezel area BZA. The transmission area TA may be an area, in which the images IM are displayed. The user visually recognizes the images IM through the transmission area TA. In an embodiment, the transmission area TA is illustrated in the shape of a rounded quadrangle. However, this is illustrated as one of the embodiments, and the transmission area TA may have various shapes, and the disclosure is not limited to an embodiment.

The bezel area BZA is next (adjacent) to the transmission area TA. The bezel area BZA may have a predetermined color. The bezel area BZA may be wound around the transmission area TA. Accordingly, the shape of the transmission area TA may be substantially defined by the bezel area BZA. However, this is illustrated as one of the embodiments, and the bezel area BZA may be next (adjacent) to only one side of the transmission area TA or may be omitted.

The display device DD may sense an external input that is applied from the outside. The external input may include various types of inputs that are provided from the outside of the display device DD. In an embodiment, as well as a contact by a portion of a body, such as the user's hand US_F, or a contact by a separate device (e.g., an active pen or a digitizer), the external input may include an external input (e.g., hovering) that is applied when the user's hand US_F approaches the display device DD or is next (adjacent) to the display device DD within a predetermined distance, for example. In addition, the external input may have various types, such as force, pressure, temperature, light, or the like.

The display device DD may include a window WM and housing EDC. In an embodiment, an appearance of the display device DD may be implemented by coupling the window WM and the housing EDC.

A front surface of the window WM defines the display surface IS of the display device DD. The window WM may include an optically transparent insulating material. In an embodiment, the window WM may include glass or plastic, for example. The window WM may include a multi-layer structure or a single layer structure. In an embodiment, the window WM may include a plurality of plastic films that are bonded to each other by an adhesive or may have a glass substrate and a plastic film that are bonded to each other by an adhesive, for example.

The display device in the embodiment may be applied to various electronic devices. The electronic device in an embodiment may include the above-described display device, and may further include modules or devices having additional functions in addition to the display device.

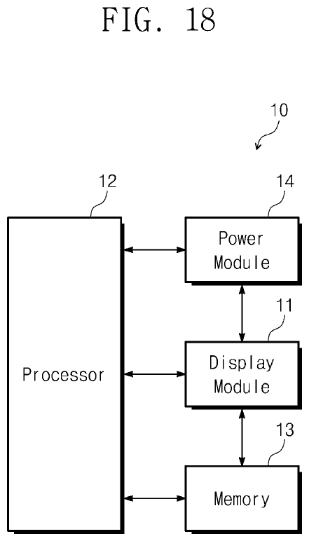

FIG. 18 is a block diagram of an embodiment of an electronic device. Referring to FIG. 18, an electronic device 10 in an embodiment may include a display module 11, a processor 12, a memory 13, and a power module 14.

The processor 12 may include at least one of a central processing unit (“CPU”), an application processor (“AP”), a graphic processing unit (“GPU”), a communication processor (“CP”), an image signal processor (“ISP”), and a controller. The processor 12 may control an operation of the display device in the embodiments of the disclosure.

Data information that are desired for an operation of the processor 12 or the display module 11 may be stored in the memory 13. When the processor 12 executes an application stored in the memory 13, an image data signal and/or an input control signal may be transmitted to the display module 11, and the display module 11 may process the provided signal and output image information through a display screen.

The power module 14 may include a power supply module, such as a power adapter or a battery device, and a power conversion module that converts electric power supplied by the power supply module to generate electric power that is desired for an operation of the electronic device 10.

The above-described electronic device 10 includes the display device described in the above embodiments, and at least one of the components of the electronic device 10 may be included in the display device. Furthermore, some of the individual modules that are functionally included in one module may be included in the display device, and others may be provided separately from the display device. In an embodiment, the display device includes a display module 11, and the processor 12, the memory 13, and the power module 14 may be provided in the form of other devices in the electronic device 10 rather than the display device, for example.

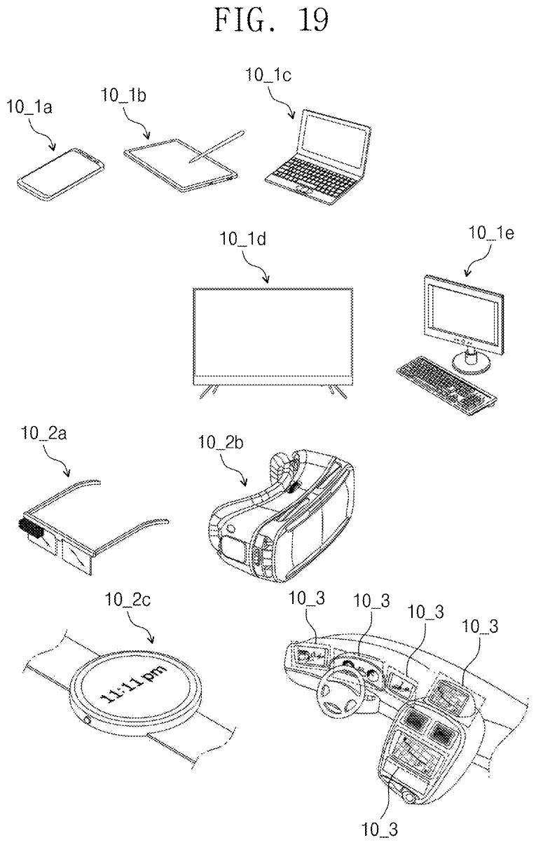

FIG. 19 is schematic diagrams of embodiments of electronic devices.

Referring to FIG. 19, various electronic device, to which the display devices in embodiments is applied, may include not only an electronic device for displaying an image, such as a smartphone 10_1a, a tablet PC 10_1b, a laptop computer 10_1c, a television (“TV”) 10_1d, and a monitor 10_1e for a desk, and but also a wearable electronic device including a display module, such as smart glasses 10_2a, a head-mounted display 10_2b, and a smart watch 10_2c, and an electronic device 10_3 for a vehicle including a display module, such as a center information display disposed in an instrument panel for a vehicle, a center fascia, and a dash board, and a room mirror display.

The magnet bar applied to the sputtering apparatus may include a plurality of magnet modules. Each of the plurality of magnet modules may include a plurality of permanent magnets and a plurality of electromagnets. According to the disclosure, the plurality of electromagnets may form a magnetic field to reinforce or offset the magnetic field generated by the plurality of permanent magnets. Accordingly, the intensity of the magnetic field may be adjusted depending on the position of the target.

Although an embodiment of the disclosure has been described for illustrative purposes, those skilled in the art will appreciate that various modifications, and substitutions are possible, without departing from the scope and spirit of the disclosure as disclosed in the accompanying claims.

Accordingly, the technical scope of the disclosure is not limited to the detailed description of this specification, but should be defined by the claims.

What is claimed is:

1. A sputtering apparatus comprising:
a magnet bar including a plurality of magnet modules, each of the plurality of magnet modules including:
a yoke;
a first permanent magnet;
a second permanent magnet;
a first electromagnet; and
a second electromagnet; and
a target module spaced apart from the magnet bar, and disposed above the magnet bar,
wherein the first permanent magnet and the second permanent magnet are disposed on a top surface of the yoke and spaced apart from each other, and
wherein each of the first electromagnet and the second electromagnet is disposed between the first permanent magnet and the second permanent magnet, and is provided in a form of being wounded on a portion of the yoke.

2. The sputtering apparatus of claim 1, wherein the first permanent magnet includes:
a first part and a second part extending in a first direction, and
wherein the second permanent magnet is disposed between the first part and the second part in a second direction crossing the first direction.

3. The sputtering apparatus of claim 2, wherein the first electromagnet is disposed between the first part and the second permanent magnet in the second direction, and the second electromagnet is disposed between the second part and the second permanent magnet in the second direction.

4. The sputtering apparatus of claim 3, wherein the first electromagnet is wound around the yoke in a coil form between the first part and the second permanent magnet,
wherein the second electromagnet is wound around the yoke in a coil form between the second part and the second permanent magnet, and
wherein a direction, in which the first electromagnet is wound around the yoke, is opposite to a direction, in which the second electromagnet is wound around the yoke.

5. The sputtering apparatus of claim 4, wherein the yoke includes:
a first through-hole provided between the first part and the second permanent magnet, and through which the first electromagnet passes; and
a second through-hole provided between the second part and the second permanent magnet, and through which the second electromagnet passes.

6. The sputtering apparatus of claim 3, wherein each of the plurality of magnet modules includes an internal area of the first electromagnet and the second electromagnet in a cross-section, and an external area of the first electromagnet and the second electromagnet in the cross-section.

7. The sputtering apparatus of claim 1, wherein the plurality of magnet modules includes a first magnet module, a second magnet module, and a third magnet module arranged in a first direction, and
wherein the first magnet module is disposed between the second magnet module and the third magnet module, in the first direction.

8. The sputtering apparatus of claim 7, wherein a direction, in which the first electromagnet of the first magnet module is wound around the yoke, is opposite to a direction, in which the first electromagnet of the second magnet module and the first electromagnet of the third magnet module are wound around the yoke, and
wherein a direction, in which the second electromagnet of the first magnet module is wound around the yoke, is opposite to a direction, in which the second electromagnet of the second magnet module and the second electromagnet of the third magnet module are wound around the yoke.

9. The sputtering apparatus of claim 1, wherein a distance between at least one of the plurality of magnet modules and the target module is different from distances between remaining magnet modules of the plurality of magnet modules and the target module.

10. The sputtering apparatus of claim 1, wherein the plurality of magnet modules are connected to each other in parallel, and
wherein the first electromagnet and the second electromagnet are connected to each other in series.

11. The sputtering apparatus of claim 10, wherein the first electromagnet and the second electromagnet are connected to a direct-current-to-direct-current power source.

12. The sputtering apparatus of claim 10, wherein the magnet bar further includes:
a plurality of resistors connected to the plurality of magnet modules, respectively, and
wherein each of the plurality of resistors is a variable resistor.

13. The sputtering apparatus of claim 10, wherein the magnet bar further includes:
a plurality of switching circuits connected to the plurality of magnet modules, respectively, and
wherein each of the plurality of switching circuits includes a plurality of switching elements and a plurality of sub-resistors connected to the plurality of switching elements, respectively, and having different resistance values from each other.

14. The sputtering apparatus of claim 10, wherein the magnet bar further includes:
a plurality of direct-current-to-direct-current power sources connected to the plurality of magnet modules, respectively.

15. The sputtering apparatus of claim 1, wherein the magnet bar further includes:
a cooling element disposed on a bottom surface of the yoke.

16. The sputtering apparatus of claim 1, wherein the magnet bar further includes:
a cooling water line disposed on a bottom surface of the yoke or disposed in an interior of the yoke.

17. A sputtering apparatus comprising:
a magnet bar including a plurality of magnet modules and a plurality of resistors connected to the plurality of magnet modules, respectively, each of the plurality of magnet modules including:
a yoke;
a first electromagnet; and
a second electromagnet; and
a target module spaced apart from the magnet bar, and disposed above the magnet bar,
wherein the first electromagnet and the second electromagnet are provided in a form of being wound around a portion of the yoke.

18. The sputtering apparatus of claim 17, wherein each of the plurality of magnet modules further includes:
a first permanent magnet and a second permanent magnet,
wherein the first permanent magnet and the second permanent magnet are disposed on a top surface of the yoke and spaced apart from each other, and
wherein each of the first electromagnet and the second electromagnet is disposed between the first permanent magnet and the second permanent magnet.

19. The sputtering apparatus of claim 18, wherein the first permanent magnet includes:
a first part and a second part extending in a first direction, and
wherein the second permanent magnet is disposed between the first part and the second part in a second direction crossing the first direction.

20. An electronic device comprising:
a display device manufactured by a sputtering apparatus; and
a processor configured to drive the display device,
wherein the sputtering apparatus includes:
a magnet bar including a plurality of magnet modules, each of the plurality of magnet modules including:
a yoke;
a first permanent magnet;
a second permanent magnet; a first electromagnet; and
a second electromagnet; and
a target module spaced apart from the magnet bar, and disposed above the magnet bar,
wherein the first permanent magnet and the second permanent magnet are disposed on a top surface of the yoke and spaced apart from each other, and
wherein each of the first electromagnet and the second electromagnet is disposed between the first permanent magnet and the second permanent magnet, and is provided in a form of being wounded on a portion of the yoke.
